(19) United States
(12) Patent Application Publication
(10) Pub. No.: US 2005/0289409 A1
(43) Pub. Date: Dec. 29, 2005

(54) Parallel data bus

(75) Inventors: Michael Smola, Munich (DE); Berndt Gammel, Markt Schwaben (DE); Gerd Dirscherl, Munich (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/165,823

(22) Filed: Jun. 23, 2005

(30) Foreign Application Priority Data
Jun. 24, 2004 (DE) 10 2004 030 602.8

(51) Int. Cl. G01R 31/28; G11C 29/00

(52) U.S. Cl. 714/712

(57) ABSTRACT

A parallel data bus having a plurality of bus lines, and a bus mode switching device for switching between data transmission at a high data transmission rate and data transmission at high data integrity.

### CROSS-REFERENCE TO RELATED APPLICATION

This application claims priority to German Patent Application Serial No. 102004030602.8, filed Jun. 24, 2004, and which is incorporated herein by reference in its entirety.

### FIELD OF THE INVENTION

The invention relates to a parallel data bus with a bus mode changeover device and to a method for operating such a parallel data bus.

### BACKGROUND OF THE INVENTION

When transmitting data over a parallel bus, it is generally necessary for the data to be protected against corruption during transmission. In this case, corruption may arise on account of transmission errors or deliberate manipulation of the data. Particularly with applications which place high demands on data integrity, such as chip cards, it is absolutely necessary to ensure data integrity. The fundamental property of chip cards, of course, is that they provide a safe environment for data and programs. If it were relatively easy to read data from chip cards without authorization, they would then have no significant difference from a storage medium.

Chip card manufacturers make a considerable amount of effort to ensure that it is not possible to manipulate data which are stored or handled on a chip card controller. To be able to recognize attacks at the physical level, sensors are incorporated in the chip card controller, for example. Such sensors can detect changes in the temperature, in the supply voltage or in the clock frequency, for example, or can detect the incidence of light inside a controller. As a further protective measure, special chip covers, “shields”, are used as protective layers which are damaged in the event of an attack. The damage then results in a change in resistance or capacitance which can be detected and evaluated. If an attack is detected, appropriate countermeasures can then be taken which make it impossible, by way of example, to read security-related data, such as secret keys.

A further possibility for ensuring data integrity is to use error detection codes (EDC). In order to prevent very sensitive data contents, such as program code, keys, access conditions, pointer structures and the like, from being altered, the data transported on buses are allocated a checksum. This checksum is transmitted together with the data which are to be monitored and, following transmission, is compared with the newly calculated checksum for the received date. If the data have been altered during transmission via the bus, then the checksums ideally differ and an alarm can be triggered or the data can be rejected and transmitted once again.

A very simple and therefore widely used checksum method is the parity check. These methods involve a parity bit being formed for each word and transmitted concurrently. The parity bit is set such that in the event of uneven parity an uneven number of bits is always set to 1, and in the event of even parity an even number of bits is always set to 1.

Since an even number of changed bits is not detected by the parity check, XOR checksums are used in practice, these being calculated by consecutively XORing all of the data bytes, and therefore also being known as a longitudinal redundancy check. However, it is not possible to detect the swapping of two bytes or multiple errors at the same bit position.

To overcome these drawbacks, CRC (Cyclic Redundancy Check) checksums are used. The checksum is generated by a cyclic shift register with feedback and also allows multiple errors to be detected.

From the field of cryptology, more complex signatures are also known, such as the MAC (Message Authentification Code), but these can be checked only if the secret key for them is known.

A drawback of using sensors to ensure data integrity is that normally a high level of development complexity is required for maintaining, tranferring, and further developing the sensors within and outside of product families. In the case of analogue sensors, there is the additional problem of calibrating them such that normal operation of the circuit is ensured under fluctuating ambient conditions while attacks are reliably detected. By way of example, if the aim is to detect an attack caused by an undervoltage, then the voltage limit needs to be chosen to be high enough for this undervoltage to be reliably detected. At the same time, this limit must not be so high that the circuit is no longer capable of operating on account of dirty contacts. Stipulating the response threshold of sensors is additionally made more difficult by variations in production and technology. In addition, such sensors also require a not insignificant surface area for integration on a chip, which increases chip costs.

A drawback of using checksums to ensure data integrity is that additional lines are required in order to transmit the checksum information. Depending on the quality of the signatures, a not insignificant number of additional bits is required, which, especially in the case of parallel buses, can result in a significant increase in the surface area requirement and thus in costs. The additional transmission of a parity bit for an 8-bit word requires 12.5% more surface area, while an 8-bit signature for a 32-bit bus already requires more than 25% additional chip surface area.

### SUMMARY OF THE INVENTION

The invention is therefore based on the object of specifying a parallel data bus and a method for operating a parallel data bus which allows the integrity of the transmitted data to be ensured with minimal complexity.

The invention achieves the object by virtue of the parallel data bus having a bus mode changeover device which changes over between data transmission at a high data transmission rate and data transmission at high data integrity.

### BRIEF DESCRIPTION OF THE DRAWINGS

The invention is explained in more detail below using an exemplary embodiment with reference to the drawings, in which:

FIG. 1 shows a parallel data bus with a bus mode changeover device in the transmission mode with a high data transmission rate;

FIG. 2 shows a parallel data bus with a bus mode changeover device in the transmission mode with high data integrity;

FIG. 3 shows a parallel data bus with a bus mode changeover device in the transmission mode with high data integrity with an error correction option; and

FIG. 4 shows an example of implementation of a parallel data bus with a bus mode changeover device.

### DETAILED DESCRIPTION OF PREFERRED EMBODIMENTS OF THE INVENTION

A parallel data bus has a bus mode changeover device which changes over between data transmission at a high data transmission rate and data transmission at high data integrity.

The fact that already existing lines in a parallel bus can, depending on the bus mode, be used both for transmitting user data and for transmitting check data results in extremely efficient utilization of the chip surface area provided for the bus in the case of integration on a chip. For data transmissions at a high data rate and without high integrity demands, no additional chip surface area is required for unused check lines. For data transmissions at high data integrity and with a low volume of data, it is advantageously possible to use already existing bus lines, which means that costs for additional chip surface area are avoided in this case, too.

In one preferred embodiment, in the mode with a high data transmission rate, the data transmission takes place over all of the lines which are available in the bus. In this way, lines which would otherwise transmit only check data are also used for the data transmission.

In line with one development of the invention, in the mode with high data integrity, one portion of the bus lines is used to transmit user data and the other portion of the bus lines is used to transmit the check data associated with the user data. In this way, no additional lines are required for transmitting check data; advantageously, one portion of the lines of an already existing bus is used for this purpose.

Advantageously, for transmitting data at high data integrity over the bus there are check data generators for generating check data from the user data. The check data generators allow various check data to be automatically calculated from the user data and hence alterations in the data during the transmission over the bus to be detected.

In line with one development, a check data comparator is provided which compares the transmitted check data with the check data of the transmitted user data. In this way, it is possible to determine the integrity of the transmitted data immediately and to take the necessary measures if appropriate.

Advantageously, the portion of the bus lines which is provided for transmitting check data has bits put on it by a check data generator such that whenever the data in a word corresponding to the bus width are transmitted over the bus each word has as identical as possible a number of bits with high and low states. The fact that as close as possible to 16 bits with high and low states are transmitted in each data word makes it more difficult to spy out data by analyzing a current profile, for example using simple or differential power analysis (DPA).

In one advantageous embodiment, the data bus has a flexible split in the bus lines for check data and user data. As a result, there are a large number of appropriate combination options. By way of example, user data with a reduced data word length of 24 bits and an 8-bit signature can be transported together via a 32-bit bus.

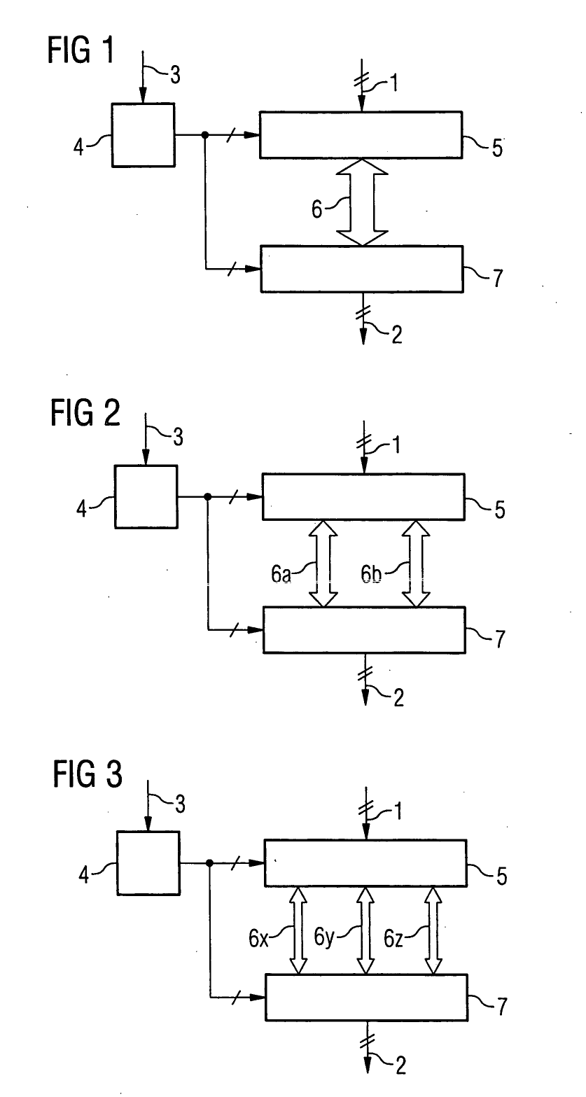

FIG. 1 shows an exemplary embodiment of a parallel data bus in the transmission mode with a high data transmission rate. The data for transmission are connected to the data conditioning unit 5 via the data input 1. The data are then transmitted to the data recovery unit 7 via the bus lines 6 and appear at the data output 2. The bus mode is selected by means of the mode signal 3, and a control logic circuit 4 actuates the data conditioning unit 5 and the data recovery unit 7 as appropriate.

In the mode shown in FIG. 1, the data produced at the data input 1 are transmitted to the data output 2 via the bus lines 6 at as high as possible a data transmission rate. All of the bus lines 6 are therefore used for transporting user data. For each transfer cycle, a respective whole data word is transported with one bit per bus line. Since no check data are being transmitted, the whole of the bus transmission capacity is available for user data. To protect the data, the data can be encrypted in the data conditioning unit 5 prior to transmission via the bus lines 6 and can then be decrypted again in the data recovery unit 7. It is likewise possible to scramble the bus lines 6, so that it is no longer possible to allocate the bits without background information. To this end, the arrangement of the bus lines 6 can be swapped around dynamically or statically by the control unit 4 in the data conditioning unit 5 and in the data recovery unit 7. Data compression in the data conditioning unit 5 using a commonly used compression method and subsequent data decompression in the data recovery unit 7 is likewise possible. To protect the data against manipulation, it is also possible to use the measures cited in the introduction, such as sensors and shields.

The bus mode with a high data transmission rate is suitable for transmitting data in large volumes and with low or no demands on data integrity. Examples of such data would be mp3 files or pictures on a digital camera, for example. This mode is unsuitable for transmitting data which have very high demands on data integrity, however. The mode signal 3 can therefore be used to instruct the control logic circuit 4 to change over the parallel bus to the mode of data transmission with high data integrity. In this mode, passwords or keys, for example, can then be transmitted securely. The low data transmission rate in this bus mode ought not to represent any great restriction in this case, since passwords and keys usually have small data volumes.

FIG. 2 shows a parallel data bus in the transmission mode with high data integrity. The arrangement is similar to the one shown in FIG. 1, and hence identical reference symbols denote the same objects. The fundamental difference from FIG. 1 is that the bus lines 6 from FIG. 1 are now used as bus lines or user data 6a and bus lines for check data 6b. The bus lines which are present now no longer transmit exclusively user data, but also the check data associated with the user data as well.

The control logic circuit 4 actuates the data conditioning unit 5 and the data recovery unit 7 such that, depending on the check data for transmission, the total number of lines is split into lines for user data 6a and lines for check data 6b. If a parity bit is chosen for the check data, for example, than in the case of a 32-bit bus it is possible to transmit user data over 31 lines and to use one line for the parity bit. If a more complex method for calculating the check data is used and, by way of example, a CRC checksum or an MAC signature is calculated, then the control logic circuit 4 is used to provide a larger number, appropriate to the check data for transmission, of lines for check data, so that the check data can be transmitted at the same time as the associated user data.

In a further variant, 32 bus lines are split into 16 lines for user data and 16 lines for check data. In this case, the check data are chosen such that in each data word precisely 16 bits are transmitted in a high state and 16 bits are transmitted in a low state. If the user data comprise 10 bits in the high state and 6 bits in the low state, for example, then the check data are chosen such that they comprise 10 bits in the low state and 6 bits in the high state. Since an identical number of bits in high and low states is transmitted each time, this makes it more difficult to use the analysis of a current profile to spy out the data, for example using DPA (Differential Power Analysis).

Other ways of splitting the bus lines 6 into lines for user data and check data are naturally possible. If this has involved the check data being transmitted at the same time as the user data hitherto, then it is also possible to transmit these data sequentially, that is to say first the data, e.g. in blocks, and then the associated check data. It is also possible to use the methods cited in the description for FIG. 1, such as encryption, scrambling and other measures for protecting the data additionally or in combination with the check data.

To date, when splitting the bus lines into lines for used data 6a and check data 6b, only error detection but no error correction is possible. If any corruption or a transmission error is detected, the arrangement described in FIG. 2 is normally used to reject the erroneous data and to request fresh transmission of the data or to trigger an alarm. The flexible splitting of the bus lines 6 by the control logic circuit 4, together with the data conditioning unit 5 and the data recovery unit 7, also allow error correction for the data which are to be transmitted, however, as shown in FIG. 3. To this end, by way of example, the bus lines 6 are split into three parallel buses 6x, 6y and 6z, and identical data are transmitted via each of the three sub-buses 6x, 6y and 6z. Using a “2-out-of-3” decision, it is possible not only to detect with a high level of probability which of the three sub-buses 6x, 6y, 6z has had the data altered on it, but also subsequently to decide which of the three sub-buses have unaltered data and then transmit them.

In a further variant, the data are not transmitted in triplicate but rather in duplicate, but in each case together with check data, as described in FIG. 2. It is also possible to use error correction algorithms, such as the Reed-Solomon method, to correct errors.

In FIGS. 2 and 3, the data conditioning unit 5 and the data recovery unit 7 undertake a plurality of functions. The data produced at the data input 1 are stored in a register and are divided in accordance with the user data word length. By way of example, a 32-bit word can thus be split into two 16-bit subwords, which are then transmitted sequentially with their respective check data. To be able to calculate check data from the subwords, the data conditioning unit 5 has multiplexers which can be used to select which subwords are to be forwarded to the check data generators likewise contained in the data conditioning unit 5. The check data generator then calculates the desired check data, such as the parity bit, or a signature. The check data are then transferred to the bus lines 6 via a bus driver together with the user data.

The data recovery unit 7 compares the check data with the check data calculated from the transmitted user data. If these data are identical, no transmission error has been detected and the subwords are complied to form a word again and are forwarded to the data output 2. If the transmitted data are detected to be corrupt, an alarm can be output, a fresh data transmission can be requested, an operation can be aborted or data can be rejected.

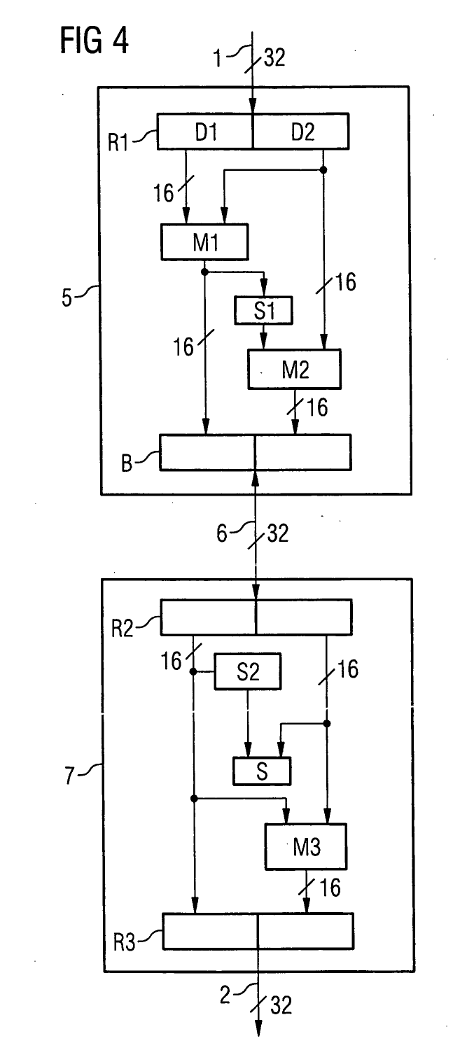

FIG. 4 shows an example of implementation in which the data conditioning unit 5 and the data recovery unit 7 are shown in detail. In the example, a 32-bit data word is transmitted, with data transmission at high integrity involving 16 bits being used for user data and 16 bits being used for check data. It goes without saying that it is also possible to use other data word lengths and a different split for the lines 6 between user data and check data. It is also readily possible to use elements for encrypting or for scrambling the bus lines 6, or for data compression, too; for the sake of clarity, these have not been shown, however, like the control logic circuit 4.

First, FIG. 4 will be used to describe the bus mode with a high data transmission rate. A 32-bit word is split into two 16-bit subwords D1 and D2 and is buffer-stored in register R1. In this case, the control logic circuit 4 actuates the multiplexers M1 and M2 such that the subword D1 is transmitted to the bus driver B via M1 and the subword D2 is transmitted to the bus driver B via M2. The original 32-bit data word is thus transmitted unchanged via the bus lines 6 to the data recovery unit 7, where it is buffer-stored in register R2. The multiplexer M3 is used to forward the semi-word D2 to the register R3 and to output the original 32-bit data word, comprising the subwords D1 and D2, at the data output 2. No check data are calculated, and hence transmission errors cannot be detected. However, since all of the lines 6 are being used for data transmission, a high data transmission rate is possible.

A description will now be given of the data transmission in the bus mode with high data integrity. In this case, the 32-bit data word is again buffer-stored in the register R1. The transmission of the left-hand data word D1 together with the associated check data and of the right-hand data word D2 with the associated check data takes place sequentially. If the data have not been changed by corruption or data transmission errors during transmission over the bus lines 6, the semi-words D1 and D2 in the register R3 are compiled to form a 32-bit word again and are output at the data output 2.

The individual steps in the data transmission in the bus mode with high data integrity will now be described in detail with reference to FIG. 4. First, the left-hand data word D1 is transmitted via the multiplexer M1, and a copy thereof is transmitted to the check data generator S1. The multiplexer M2 is used to forward the calculated check data, so that the bus driver with register B contains the semi-data word D1 and the check data associated with the semi-data word D1. Following transmission via the bus lines 6, the data recovery unit 7 again calculates the signature of the left-hand semi-word D1 in a second check data generator S2, and this is compared with the transmitted check data in a check data comparator S. If the check data differ, an error is output or an alarm is triggered. The multiplexer M3 can now be used to write either the semi-word D1 or the associated check data to the right-hand half of the register R3. It does not matter what is stored in the right-hand word half of the register R3 at this time, since the content is overwritten later. What is important is that the left-hand word half of the register R3 is used to store the original left-hand word half D1.

In a second step, the right-hand word half D2 of the original data word from register R1 is forwarded via the multiplexer M1. A copy is again routed to the check data generator S1 and via the multiplexer M2 to the bus driver B. The bus driver B now contains the data D2 and the associated check data. The data are again transmitted via the bus lines 6 to the data recovery unit 7 and are stored in the register R2. From the left-hand register content, the check data are then again generated in a further check data generator S2 and are compared with the transmitted check data from D2 in the check data comparator S. If they are identical, they are forwarded, otherwise an error message is triggered.

The left-hand half of the register R3 is disabled for write access, since it already contains the left-hand word half D1 of the original data. The right-hand word half D2 of the original data is stored in the right-hand word half of the register R3 via the multiplexer M3, so that the register R3 now contains the two word halves D1 and D2 and these can be output to the data output 2. Instead of disabling the left-hand half of the register R3 for write access after the first step, it is also possible to store the original left-hand data word D1 in a further memory and later to compile it and the right-hand semi-word D2 to form a 32-bit data word.

The control logic circuit 4 (not shown) actuates the registers R1, R2 and R3, the bus driver B and the multiplexers M1, M2 and M3 such that, depending on the bus mode, the data are transmitted at a high data transmission rate or at high data integrity. The splitting of the data lines into user data lines and check data lines is in line with the type of check data, such as no check data, parity bit, CRC or signature, and is prescribed by the mode signal 3 and implemented by the control logic circuit 4. The control logic circuit 4 additionally controls the individual steps of data transmission from those described above and stipulates their timing.

1. A parallel data bus comprising:
a plurality of bus lines; and
a bus mode switching device for switching between data transmission at a high data transmission rate and data transmission at high data integrity.

2. The parallel data bus as claimed in claim 1, wherein during a high data transmission rate, data transmission takes place over all of the available bus lines.

3. The parallel data bus as claimed in claim 1, wherein during the high data integrity transmission, one portion of the bus lines is used to transmit user data and the other portion of the bus lines is used to transmit check data associated with the user data.

4. The parallel data bus as claimed in claim 1, further comprising a check data generator for generating check data from user data during the high data integrity transmission.

5. The parallel data bus as claimed in claim 4, further comprising a check data comparator which compares transmitted check data with the check data of the transmitted user data.

6. The parallel data bus as claimed in claim 4, wherein the check data generator places bits on the bus lines for transmitting check data, such that whenever a word corresponding to the bus width is transmitted over the bus, each word has as identical as possible a number of bits with high and low states.

7. The parallel data bus as claimed in claim 3, wherein a division in the bus lines into lines for check data and user data is flexible.

8. A method for operating a parallel data bus, comprising the steps of:
detecting a bus mode; and
selecting, based on the bus mode, between data transmission at a high data transmission rate and data transmission at high data integrity.

9. The method as claimed in claim 8, wherein following selection of a bus mode for transmitting data at a high data transmission rate, using all of the lines of the bus for transmitting user data.

10. The method as claimed in claim 8, wherein following selection of a bus mode for transmitting data at high data integrity, using one portion of the lines of the bus for transmitting user data and the remaining portion of the lines for transmitting check data which are obtained from the user data.

11. The method as claimed in claim 8, wherein the check data are signatures for the user data.

12. The method as claimed in claim 10, further comprising the step of placing bits on the lines for check data such that whenever a word corresponding to the bus width is transmitted over the bus each word has an identical number of bits with high and low states.

13. A parallel data bus comprising:
a plurality of bus lines; and
a bus mode switching means for switching between data transmission at a high data transmission rate and data transmission at high data integrity.

14. The parallel data bus as claimed in claim 13, wherein during a high data transmission rate, data transmission takes place over all of the available bus lines.

15. The parallel data bus as claimed in claim 13, wherein during the high data integrity transmission, one portion of the bus lines is used to transmit user data and the other portion of the bus lines is used to transmit check data associated with the user data.

16. The parallel data bus as claimed in claim 13, further comprising check data generating means for generating check data from user data during the high data integrity transmission.

17. The parallel data bus as claimed in claim 16, further comprising a check data comparing means for comparing transmitted check data with the check data of the transmitted user data.

18. The parallel data bus as claimed in claim 16, wherein the check data generating means places bits on the bus lines for transmitting check data, such that whenever a word corresponding to the bus width is transmitted over the bus, each word has as identical as possible a number of bits with high and low states.

19. The parallel data bus as claimed in claim 15, wherein a division in the bus lines into lines for check data and user data is flexible.

20. A computer program having a program code for performing a method for receiving instructions, comprising the steps of: (a) detecting a bus mode; and (b) selecting, based on the bus mode, between data transmission at a high data transmission rate and data transmission at high data integrity, when the computer program runs on a computer.

21. The computer program as claimed in claim 20, wherein following selection of a bus mode for transmitting data at a high data transmission rate, using all of the lines of the bus for transmitting user data.

22. The computer program as claimed in claim 20, wherein following selection of a bus mode for transmitting data at high data integrity, using one portion of the lines of the bus for transmitting user data and the remaining portion of the lines for transmitting check data which are obtained from the user data.

23. The computer program as claimed in claim 20, wherein the check data are signatures for the user data.

24. The computer program as claimed in claim 22, further comprising the step of placing bits on the lines for check data such that whenever a word corresponding to the bus width is transmitted over the bus each word has an identical number of bits with high and low states.

25. A system for operating a parallel data bus comprising:
a processor;
a memory communicatively coupled to the processor; and
software executing in the processor configured to:
a) detect a bus mode; and
b) select, based on the bus mode, between data transmission at a high data transmission rate and data transmission at high data integrity.

26. The system as claimed in claim 25, wherein following selection of a bus mode for transmitting data at a high data transmission rate, using all of the lines of the bus for transmitting user data.

27. The system as claimed in claim 25, wherein following selection of a bus mode for transmitting data at high data integrity, using one portion of the lines of the bus for transmitting user data and the remaining portion of the lines for transmitting check data which are obtained from the user data.

28. The system as claimed in claim 25, wherein the check data are signatures for the user data.

29. The system as claimed in claim 27, further comprising the step of placing bits on the lines for check data such that whenever a word corresponding to the bus width is transmitted over the bus each word has an identical number of bits with high and low states.

30. A system for operating a parallel data bus comprising:
a data conditioning unit for transmitting user data;
parallel bus lines;
a data recovery unit for receiving the transmitted user data via the parallel bus lines; and
a bus mode switching device for switching between data transmission at a high data transmission rate and data transmission at high data integrity.

31. The system of claim 30, wherein during a high data transmission rate, data transmission takes place over all of the available bus lines.

32. The system as claimed in claim 30, wherein during the high data integrity transmission, one portion of the bus lines is used to transmit user data and the other portion of the bus lines is used to transmit check data associated with the user data.

33. The system as claimed in claim 30, wherein the data conditioning unit comprises a check data generator for generating check data from user data during the high data integrity transmission.

34. The system as claimed in claim 33, wherein the data recovery unit comprises a check data comparator which compares transmitted check data with the check data of the transmitted user data.

35. The system as claimed in claim 33, wherein the check data generator places bits on the bus lines for transmitting check data, such that whenever a word corresponding to the bus width is transmitted over the bus, each word has as identical as possible a number of bits with high and low states.

36. The system as claimed in claim 32, wherein a division in the bus lines into lines for check data and user data is flexible.
